(19) United States
(12) Patent Application Publication
(10) Pub. No.: US 2011/0042784 A1
(43) Pub. Date: Feb. 24, 2011

(54) Mechanical Barrier Element for Improved Thermal Reliability of Electronic Components

(75) Inventors: David L. Edwards, Poughkeepsie, NY (US); Jean-Luc Landreville, Grandby (CA); Kathryn R. Lange, Fishkill, NY (US); Carl Savard, Granby (CA); Kamla K. Sikka, Hopewell Junction, NY (US); Hilton T. Toy, Hopewell Junction, NY (US)

Correspondence Address: IBM MICROELECTRONICS;INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 12/854,973

(22) Filed: Aug. 12, 2010

(30) Foreign Application Priority Data
Aug. 24, 2009 (CA) 2676495

(51) Int. Cl. H01L 23/29; H01L 21/50; H01L 23/52

(52) U.S. Cl. 257/532; 438/124; 257/499; 257/724; 257/E21.499; 257/E23.141; 257/E23.117

(57) ABSTRACT

Embodiments of the invention are generally related to packaging of integrated circuit devices, and more specifically to the placement of thermal paste for cooling an integrated circuit device during operation. A barrier element may be placed along at least one side of an integrated circuit chip. The barrier element may contain thermal paste pumped out during expansion and contraction of the package components to areas near the chip. The barrier element may also form a reservoir to replenish thermal paste that is lost during thermal pumping of the paste.

### BACKGROUND OF THE INVENTION

1. Field of the Invention

The present invention is generally related to packaging of integrated circuit devices, and more specifically providing a thermal paste for cooling an integrated circuit device during operation.

2. Description of the Related Art

Since the invention of the transistor, dissipation of heat during operation has been an important consideration in semiconductor device package design. Heat can damage the delicate and tiny structures which allow transistors to function as intended in a semiconductor device. Power drawn by transistors and other electronic devices must be dissipated to avoid build up of heat and the development of high temperatures which can degrade the devices by such mechanisms as dopant diffusion, metal migration including solder softening and reflow, or the like.

As semiconductor devices become smaller and smaller, it has become more difficult to provide efficient heat dissipation mechanisms. Current designs provide thermal pastes in conjunction with heat sinks that facilitate internal cooling of the semiconductor devices. Thermal pastes are generally high thermal conductivity interface materials that fill the gaps between the back-side of integrated circuit chips and the inside surfaces of heat sinks. Generally, semiconductor device package components, like the back surface of the integrated circuit and the inside of the cap must be chemically compatible with the thermal paste, so that the paste can adhere to them. Furthermore, the package must be designed such that the thermal paste filled chip-to-heat sink gap has sufficient thickness that it will form a reliable and efficient heat dissipating structure.

### SUMMARY OF THE INVENTION

The present invention is generally related to packaging of integrated circuit devices, and more specifically to the placement of thermal paste for cooling an integrated circuit device during operation.

One embodiment of the invention provides an integrated circuit package, generally comprising a substrate, an integrated circuit chip coupled with the substrate, and a cap configured as a heat dissipation element, wherein a thermal paste forms an interface between a top surface of the integrated circuit chip and a bottom surface of the cap. The integrated circuit package further comprises at least one barrier element formed proximate to at least one side of the integrated circuit chip, wherein a region between the barrier element and the at least one side of the integrated circuit chip defines a reservoir for excess thermal paste pumped from between the top surface of the integrated circuit chip and the bottom surface of the cap.

Another embodiment of the invention provides a method for fabricating an integrated circuit package. The method generally comprises providing an integrated circuit chip coupled with a substrate, placing a barrier element on the substrate proximate to at least one side of the substrate, depositing a thermal paste on a portion of a top surface of the integrated circuit chip, and pushing the thermal paste towards the integrated circuit chip with a surface of a cap, wherein the pushing spreads the thermal paste over the top surface of the integrated circuit chip and into a region between the barrier element and the at least one side of the substrate to form a reservoir of thermal paste.

Yet another embodiment of the invention provides an integrated circuit package, generally comprising a plurality of integrated circuit chips coupled with a substrate, a cap configured as a heat dissipation element, wherein a thermal paste forms an interface between top surfaces of the integrated circuit chips and a bottom surface of the cap, and at least one barrier element formed proximate to at least one side of at least one of the integrated circuit chips, wherein a region between the barrier element and the at least one side of the integrated circuit chip defines a reservoir for excess thermal paste pumped from between the top surface of the integrated circuit chip and the bottom surface of the cap.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 illustrates an exemplary integrated circuit package according to an embodiment of the invention.

FIG. 2 illustrates another exemplary integrated circuit package according to an embodiment of the invention.

FIG. 3 illustrates an exemplary integrated circuit package according to an embodiment of the invention.

FIGS. 4A-4E illustrate steps for fabricating an integrated circuit package according to an embodiment of the invention.

FIG. 5 is a flow diagram of exemplary operations performed during fabrication of an integrated circuit package according to an embodiment of the invention.

### DETAILED DESCRIPTION OF THE PREFERRED EMBODIMENTS

Embodiments of the invention are generally related to packaging of integrated circuit devices, and more specifically to the placement of thermal paste for cooling an integrated circuit device during operation. A barrier element may be placed along at least one side of an integrated circuit chip. The barrier element may contain thermal paste pumped out during expansion and contraction of the package components to areas near the chip. The barrier element may also form a reservoir to replenish thermal paste that is lost during thermal pumping of the paste.

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

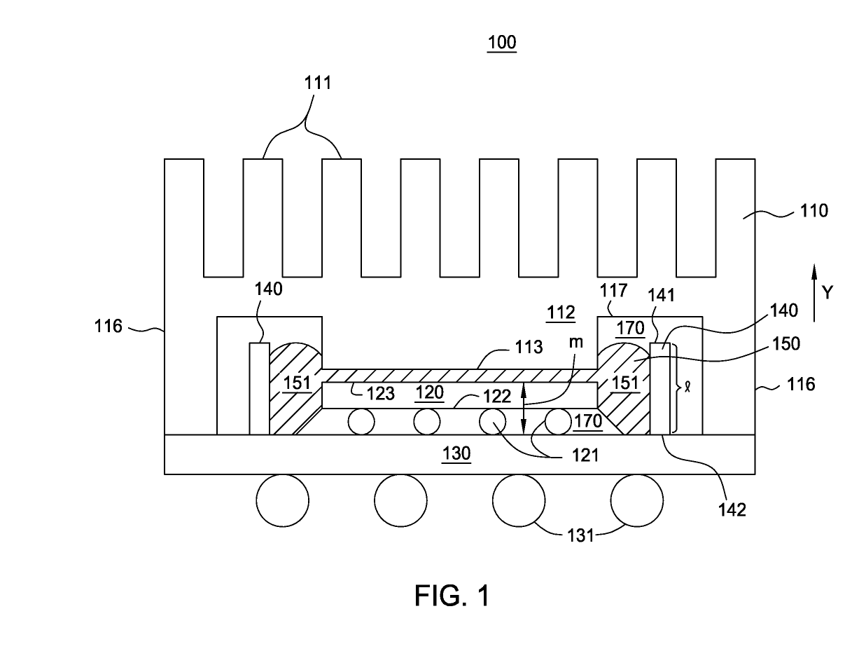

FIG. 1 illustrates a cross-sectional view of an integrated circuit package 100 according to an embodiment of the invention. As illustrated in FIG. 1, the package 100 includes a cap 110, an integrated circuit chip 120 (hereinafter referred to simply as chip), a substrate 130, and at least one barrier element 140. The cap 110 may be a heat sink configured to dissipate heat generated by the integrated chip 120. The cap 110 may include materials that are good conductors of heat. For example, in some embodiments, the cap 110 may be formed with copper, aluminum, or like metals. In some embodiments, the cap 110 may be made from a metal alloy, for example, Kovar (Kovar is a trademark of Carpenter Technology Corporation), CuW, or the like. In some embodiments, the cap 110 may be made of a composite material such as, for example, Aluminum Oxide, Silicon Carbide, Aluminum-Silicon Carbide, or the like.

As illustrated in FIG. 1, in one embodiment, the cap 110 may include a plurality of fin or comb like protrusions 111. The protrusions 111 may increase the surface area of the cap 110, thereby facilitating fast and efficient dissipation of heat received from the chip 120. The cap 110 may receive heat generated by the chip 120 at a protrusion 112 which is generally located over the chip 120 and has a lower (e.g., planar) surface 113 in facing relation with the chip 120.

In one embodiment of the invention, the cap 110 may be mechanically coupled with the substrate 130. For example, in FIG. 1, a leg portion 116 of the cap 110, may be affixed to the substrate 130 using an adhesive material. Any reasonable adhesive material may be used to attach the cap 110 to the substrate 130. Exemplary adhesive materials may include, for example, epoxy, solder, silicone elastomers, or the like. While the cap 110 is shown attached to the substrate 130 in FIG. 1, in alternative embodiments, the cap 110 may instead be coupled with the barrier element 140, or may simply sit only on top of the chip 120 without being coupled with the substrate 130. In other words, the outer leg portions 116 may be omitted in some embodiments of the invention.

While the cap 110 is shown as a single solid structure, in alternative embodiments, the cap may include a plurality of independent distinct solid structures that are coupled together to form the cap 110. For example, in one embodiment, the protrusion 112 may be a separate element that is detachable from the rest of the cap 110. In embodiments where the cap 110 comprises multiple distinct structures, each of the multiple distinct structures may be formed with similar or distinct materials, for example, the same or different types of metals, plastics, ceramic, or the like.

The chip 120 may be any type of integrated circuit including, for example, processors, memory controllers, memory devices, or the like. In general, the chip 120 may include a plurality of transistors, resistors, inductors, capacitors, or other like circuit components that consume power and dissipate heat during operation. As illustrated in FIG. 1, the chip 120 may be electrically coupled with the substrate 130 by one or more solder bumps 121. A sealant layer 170 or chip underfill may also be provided to mechanically couple the chip 120 with the substrate 130 and extend the life of the solder connections which may be affected by thermal cycling due to CTE (Coefficient of Thermal Expansion) mismatch between the chip and substrate materials. In one embodiment, the sealant layer may also serve to prevent impurities from reaching the solder bumps 121 and adversely affecting the transfer of electric signals between the chip 120 and the substrate 130. Any reasonable material, for example, an epoxy resin, inorganic filler materials, or the like may be used as the sealant 170.

In one embodiment, the substrate 130 may be a wiring substrate configured to route signals from one location of the chip 120 to another location on the chip 120. The substrate 130 may also be configured to provide power and/or ground connections to the chip 120 via the solder bumps 121. In some embodiments, the substrate 130 may be configured to exchange one or more input and/or output signals with the chip 120 during operation. While not shown in FIG. 1, in some embodiments, the substrate may include a plurality of chips 120. Accordingly, in such embodiments, the substrate 130 may be configured to transfer electric signals from a first chip 120 to a second chip 120 coupled therewith. Underneath the wiring substrate 130 are multiple solder ball connections 131. The solder ball connections 131 may be used to electrically couple the substrate 130 to another device such as, for example, a printed circuit board (PCB) or a chip carrier.

As illustrated in FIG. 1, a thermal paste layer 150 may be provided in the gap between the chip 120 and the protrusion 112 of the cap 110. The thermal paste layer 150 forms a thermal interface between the chip 120 and the lower surface 113 of the protrusion 112, allowing heat to be transferred from the chip 120 to the cap 110. In one embodiment, the thermal paste 150 may include any combination of silicone oil, mineral oil, epoxy oil, aluminum oxide, zinc oxide, boron nitride, aluminum, or the like.

The integrated circuit package 100 is commonly known in the industry as a flip-chip type package structure. Under this arrangement, most of the heat generated by integrated circuit chip 120 is expected to be transferred to the cap 110. First, the heat flows from the front side 122 of integrated circuit chip 120 (i.e., a circuit area) to the back side 123 of integrated circuit chip 120. Then, the heat flows from the back side 123 of integrated circuit chip 120 to the lower surface 113 of cap 110 through thermal paste layer 150. Finally, heat flows from the surface 113 of cap 110 to the protrusions 111 of cap 110.

While a flip chip package is described herein, it should be understood that embodiments of the invention may be advantageously utilized in other chip configurations such as, for example, wire bonding configurations. In general, embodiments of the invention may be used in any type of integrated circuit package wherein transfer of heat from an integrated circuit chip to a heat sink is desired.

During operation of the chip 120, transistors and other circuit components of the integrated circuit may be turned off and on several times. The switching of transistors may result in cyclical generation of heat from the integrated circuit chip 120. Such thermal cycling may result in the expansion and contraction of the cap 110, the chip 120, and the substrate 130. The expansion and contraction, particularly expansion and contraction along the y axis (see FIG. 1), may result in pumping of the thermal paste 150, such that the thermal paste 150 moves out of the interface between the cap 110 and the integrated circuit chip 120.

The removal of thermal paste from the interface between the cap 110 and the chip 120 may be detrimental to the efficient dissipation of heat from the chip 120. For example, in prior art systems, loss of thermal paste in the interface between the chip and the cap may generate voids and/or air pockets at the interface that result in poor and uneven thermal conductivity across the interface. Such uneven and poor heat dissipation may result in damage to the chip, or to electrical components of the chip due to overheating.

Furthermore, pumped out thermal paste may be deposited at undesired locations on a substrate, thereby damaging the integrated circuit package. For example, pumped out thermal paste may interact with adhesive material used to affix the cap to the substrate, thereby loosening or even detaching the cap from the substrate.

Embodiments of the invention provide at least one barrier element 140 (two exemplary barrier elements 140 shown in FIG. 1) that is configured to contain the thermal paste material 150 within desired areas of the package 100. In one embodiment, the barrier elements 140 may be placed in close proximity to an edge of the chip 120. Accordingly, the thermal paste 150 may be contained in a region that is close to the chip 120, thereby preventing pumped out thermal paste from undesirably interacting with other package components.

In one embodiment, the barrier element 140 may be formed in a void region 170 formed between an outer leg 116 of the cap 110, and side wall portions of the chip 120 and the protrusion 112 of the cap 110, as is illustrated in FIG. 1. The barrier element 140 may be formed on the substrate 130, thereby allowing the barrier element 140 to block the flow of thermal paste 150 that is pumped out from a corresponding side of the chip 120 from flowing to undesired locations of the package 100.

As illustrated in FIG. 1, in one embodiment, a height l of the barrier element 140 may be greater than a height m of the chip 120 from a surface of the substrate 130. In a particular embodiment, the height l of the barrier element may be between about 0.1 and 3.0 mm above the height m of the chip 120, and may be between around 0.1 and 5.0 mm away from the chip edge. By providing a barrier element having a greater height than the height of the chip 120, the flow of pumped out thermal material 150 over the top of the barrier element 140 may be avoided.

The barrier element 140 may be made with any suitable material such as, for example, a ceramic, a plastic, metallic, or a composite material. In one embodiment, the barrier element 140 may be made sufficiently thin so as not to take up too much space in the package 100. For example, in one embodiment, the thickness w of the barrier element 140 may be between around 0.025 and 4.0 mm.

In one embodiment of the invention, the barrier element 140 may be coupled with both, the cap 110 and the substrate 130. For example, referring to FIG. 1, a top surface 141 of the barrier element 140 may be coupled with a surface 117 of the cap 110, and a bottom surface 142 of the barrier element 140 may be coupled with the substrate 130. In such embodiments, the barrier element 140 may be made from a flexible material capable of bending or otherwise changing its shape to accommodate for expansion/contraction of the cap 110 and/or substrate 130 during thermal cycling. Alternatively, the cap 130 may include a recess groove configured to receive a portion of the barrier element 140.

In one embodiment of the invention, a region 151 between the barrier element 140 and a side of the chip 120 may be used to store excess thermal paste that may act as a reservoir to replenish pumped out thermal paste from the interface between the chip 120 and the cap 110. For example, referring to FIG. 1, during expansion of the chip 120 and the cap 110 towards each other along the y axis, thermal paste from the interface may be pumped out into the reservoir region 151. Subsequently, during contraction of the cap 110 and the chip 120 away from each other, thermal paste from the reservoir may be sucked into the interface due to the pumping action. Therefore, the interface between the chip 120 and the cap 110 may retain a uniform layer of thermal paste. In one embodiment, the barrier element 140 may be made from a flexible material capable of changing shape in response to receiving thermal paste in the reservoir region 151 and/or the expansion/contraction of the cap 110 and substrate 130.

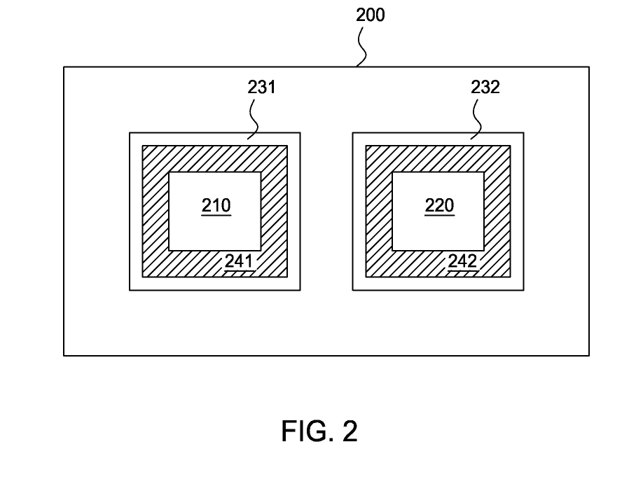

In one embodiment of the invention, a barrier element 140 may be provided along each side of a chip in an integrated circuit package. FIG. 2 illustrates a plan view of an exemplary integrated circuit package 200. For illustrative purposes a cap is not shown in FIG. 2. In one embodiment, the package 200 may include two integrated circuit chips 210 and 220, as illustrated in FIG. 2. In one embodiment of the invention, separate barrier elements may be provided for each of the integrated circuit chips 210 and 220. For example, a first barrier element 231 contains thermal paste material near the chip 210 and a second barrier element 232 contains the thermal paste near chip 220, as shown in FIG. 2. The shaded portion 241 and 242 may represent thermal paste reservoirs for each of the chips 210 and 220.

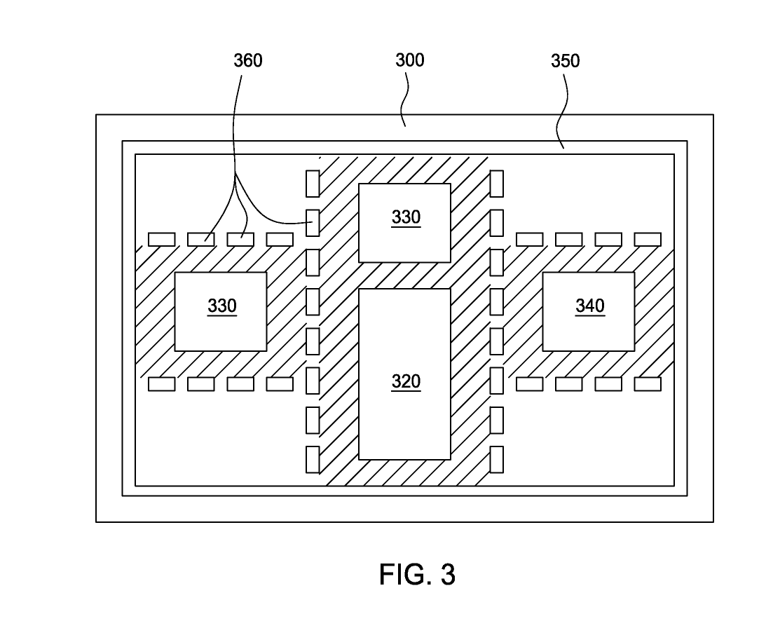

While the barrier elements are shown encompassing all sides of each chip in the integrated circuit package of FIG. 2, in alternative embodiments, the barrier element may be provided only along one or more desired sides of each chip. FIG. 3 illustrates a plan view of another integrated circuit package 300 according to an embodiment of the invention. As illustrated in FIG. 3, a single solid barrier element 350 is provided for four integrated circuit chips 310, 320, 330, and 340. As shown in FIG. 3, the barrier element 350 may be adjacent to only a one side of each of the chips 310, 320, 330, and 340.

In one embodiment of the invention a plurality of capacitors 360 may be placed in close proximity to the chips 310, 320, 330, and 340. The capacitors 360, in conjunction with the solid barrier element 350 may contain the thermal paste near the respective chips 310, 320, 330, and 340 and provide a thermal paste reservoir. For example, the shaded portions in FIG. 3 illustrate exemplary thermal paste reservoir regions in the integrated circuit package 300, according to one embodiment.

In one embodiment, the capacitors 360 may have a thickness that is greater than a thickness of the solid barrier element 350. In other words, as a barrier element, the solid barrier element 350 may take up less space on the integrated circuit chip in comparison to the capacitors 360. In one embodiment, the capacitors 360 may have one or more electrical functions such as, for example, providing for decoupling of the chips 310, 320, 330, and 340 from other package components. Furthermore, in some embodiments, the capacitors 360 may provide an additional source of power to the chips 310, 320, 330, and 340 during spikes in current requirements in any one of the chips 310, 320, 330, and 340.

While the elements 360 are described as capacitors hereinabove, in alternative embodiments, the elements 360 illustrated in FIG. 3 may also include resistors, inductors, switches, and other like circuit elements. In general, the components 360 may provide an electric function related to one or more chips in a package, and also act as a barrier element for containing thermal paste near the one or more chips.

While the barrier elements illustrated in FIGS. 2 and 3 are shown as solid rectangular barrier elements, in some embodiments, an integrated circuit chip may include a plurality of barrier element structures of any reasonable shape. Other exemplary types of barrier elements may include solid circular barrier elements, intermittently placed fin shaped barrier elements, curved barrier elements, and the like.

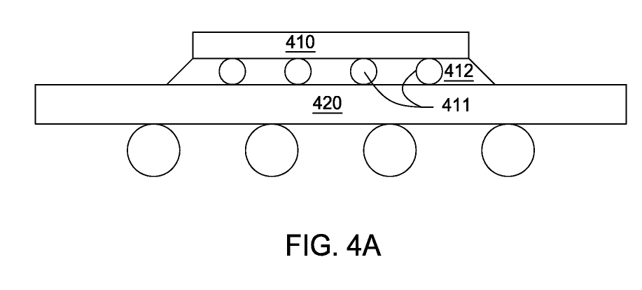

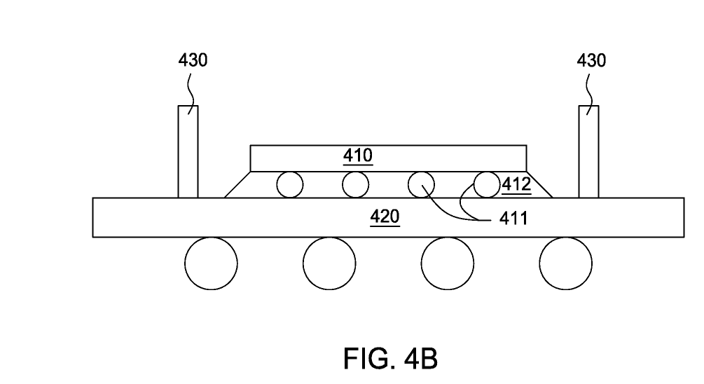

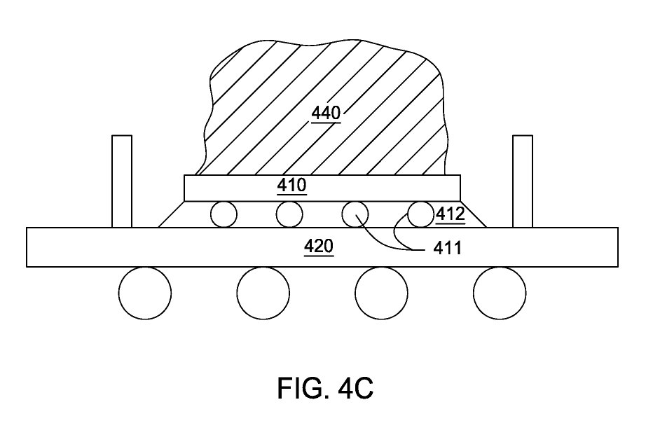

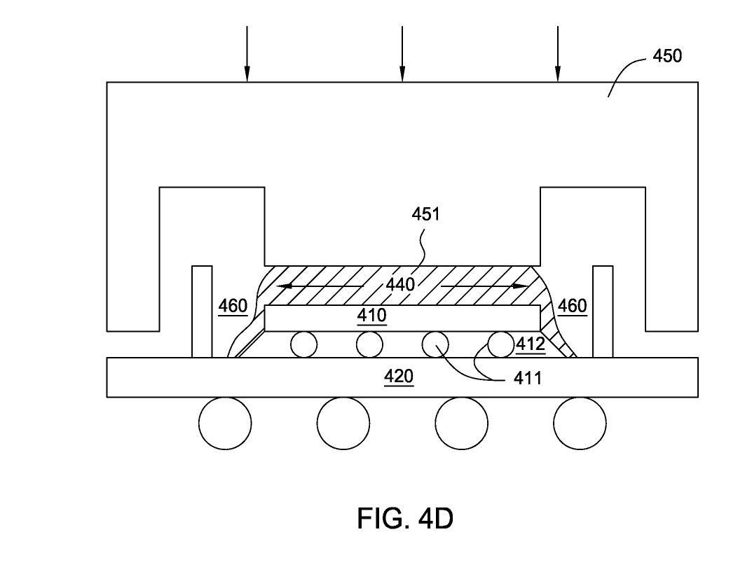

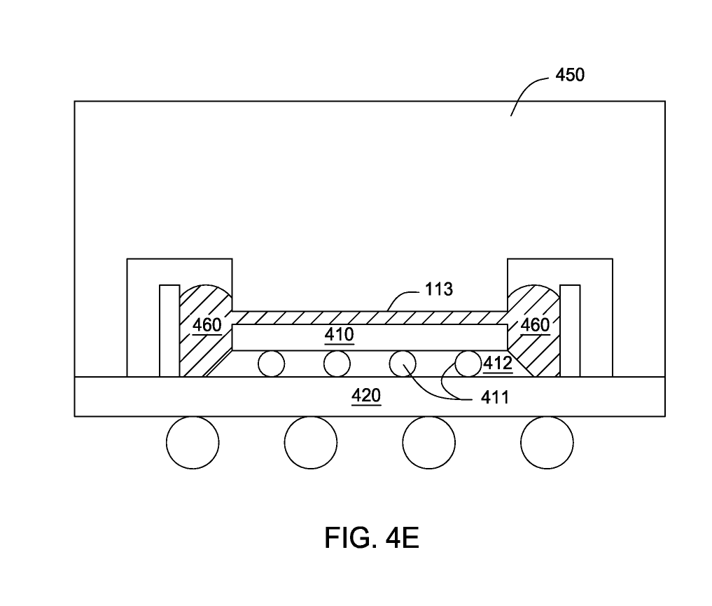

FIGS. 4A-4C illustrate an exemplary process for fabricating an integrated circuit package, according to an embodiment of the invention. As illustrated in FIG. 4A, the process may involve providing an integrated circuit chip 410 electrically and mechanically coupled with a substrate 420. The chip 410 and substrate 420 may correspond to the chip 120 and substrate 130 of FIG. 1. Accordingly, the chip 410 is shown coupled with the substrate 420 by means of solder balls 411 and an encapsulant material 412.

In one embodiment, a barrier element 430 may be affixed to the substrate 420, as illustrated in FIG. 4B. While placing the barrier element 430 on the substrate 420 after the mechanical and electrical coupling of the chip 410 to the substrate 420 is disclosed herein, in alternative embodiments, the barrier element 430 may be affixed to the substrate 420 prior to the mechanical and electrical coupling of the substrate 420 and the chip 410. The barrier element 430 may be coupled with the substrate by any reasonable means such as, for example, by using an adhesive material like silicone, epoxy, or solder (e.g., PbSn, AgSn, or the like). The barrier element 430 may represent a solid barrier element material made of, for example, ceramic, metal, plastic or composite materials. In one embodiment, the barrier element can be a material that is formed with a polymer like silicone or epoxy. Alternatively, the barrier element 430 may be a circuit component such as a capacitor, resistor, inductor, or the like.

After coupling the chip 410 and the barrier element 430 to the substrate, thermal material may be placed on an exposed surface of the chip 410. In one embodiment of the invention, thermal material 440 may be placed on the chip 410 such that the thermal material 440 covers less than the total exposed surface area of the chip 410, as is illustrated in FIG. 4C.

In one embodiment of the invention, the volume of thermal material 440 deposited over the chip 410 may be greater than a desired volume of thermal material 440 at an interface of a cap and the chip 410. In one embodiment, the volume of thermal material 440 deposited may be sufficiently large to fill a reservoir region between the barrier element 430 and the chip 410 in addition to the interface between the chip 410 and a cap.

In one embodiment, after depositing the thermal material 440 on the chip 410, the thermal material may be pushed towards the chip 410 using a surface 451 of a cap 450, as illustrated in FIG. 4D. Pushing the thermal material 440 using the surface 451 of the cap 450 may cause the thermal material 440 to spread across the entire surface of the chip 410. As the thermal material 440 is continued to be pushed down, some of the thermal material 440 may be pumped out into the reservoir region 460 between the barrier element 430 and the chip 410.

FIG. 4E illustrates the integrated circuit package after the cap 450 has been completely pushed down and brought into contact with the substrate 430. The integrated circuit package illustrated in FIG. 4E may correspond to the integrated circuit package illustrated in FIG. 1. As illustrated in FIG. 4E, the thermal paste material 440 is shown spread uniformly across the top surface of the chip 410. Furthermore, excess thermal paste 440 material is pushed into the reservoir region 460. The barrier element 430 contains the excess thermal paste material in the reservoir region 460 such that a uniform thermal paste layer is always present at the interface between the cap 450 and the chip 410 during thermal pumping of the thermal paste.

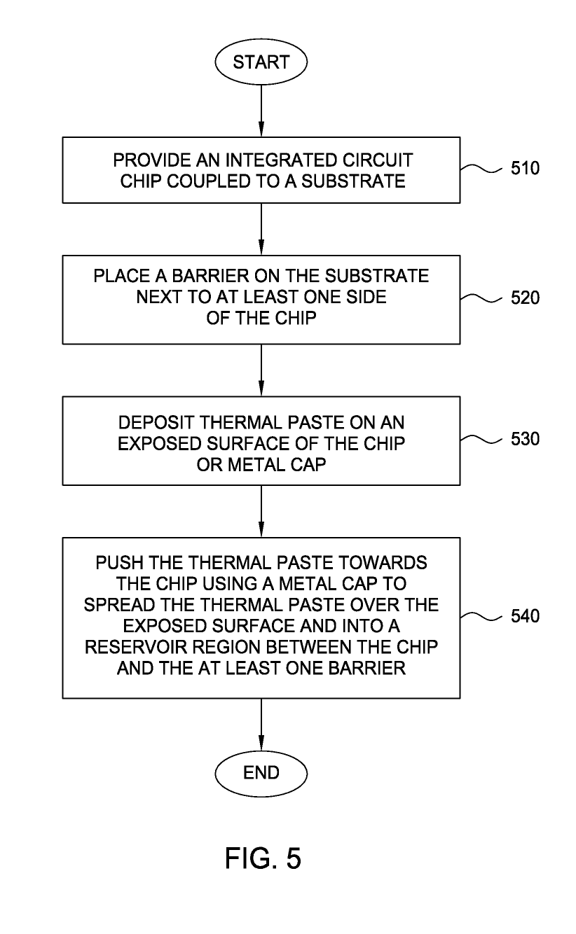

FIG. 5 is a flow diagram of exemplary operations performed during fabrication of an integrated circuit, according to an embodiment of the invention. The operations may begin in step 510 by providing an integrated circuit chip coupled with a substrate. In step 520 a barrier element may be placed on the substrate next to at least one side of the chip. In step 530, thermal paste material may be deposited on an exposed surface of the chip or metal lid. In step 540, the thermal paste material may be pushed towards the chip using a surface of a cap such that the thermal paste material is spread over the surface of the chip and into a reservoir region between the chip and the at least one barrier element.

Advantageously, by providing a barrier element configured to contain thermal paste material near an integrated circuit chip and store excess thermal paste to replenish thermal paste lost during thermal paste pumping, embodiments of the invention provide an efficient and reliable heat dissipation system.

While the foregoing is directed to embodiments of the present invention, other and further embodiments of the invention may be devised without departing from the basic scope thereof, and the scope thereof is determined by the claims that follow.

What is claimed is:

1. An integrated circuit package, comprising:
a substrate;
an integrated circuit chip coupled with the substrate;
a cap configured as a heat dissipation element, wherein a thermal paste forms an interface between a top surface of the integrated circuit chip and a bottom surface of the cap; and
at least one barrier element formed proximate to at least one side of the integrated circuit chip, wherein a region between the barrier element and the at least one side of the integrated circuit chip defines a reservoir for excess thermal paste pumped from between the top surface of the integrated circuit chip and the bottom surface of the cap.

2. The integrated circuit package of claim 1, wherein the barrier element is formed with one of a polymer, ceramic, plastic and a metal.

3. The integrated circuit package of claim 1, wherein the barrier element comprises a plurality of capacitors.

4. The integrated circuit package of claim 1, wherein the barrier element is attached to a surface of the substrate.

5. The integrated circuit package of claim 1, wherein the thermal paste comprises any one or more of:
silicone oil;
mineral oil; and
epoxy oil.

6. The integrated circuit package of claim 1, wherein the thermal paste comprises any one or more of:
aluminum oxide;
zinc oxide; and
boron nitride.

7. The integrated circuit package of claim 1, wherein the reservoir is configured to receive thermal paste from the interface between the top surface of the integrated circuit chip and the bottom surface of the cap during expansion of at least one of the integrated circuit chip and the cap.

8. The integrated circuit package of claim 1, wherein the reservoir is configured to provide thermal paste to the interface between the top surface of the integrated circuit chip and the bottom surface of the cap during contraction of at least one of the integrated circuit chip and the cap.

9. A method for fabricating an integrated circuit package, comprising:
providing an integrated circuit chip coupled with a substrate;
placing a barrier element on the substrate proximate to at least one side of the substrate;
depositing a thermal paste on a portion of a top surface of the integrated circuit chip; and
pushing the thermal paste towards the integrated circuit chip with a surface of a cap, wherein the pushing spreads the thermal paste over the top surface of the integrated circuit chip and into a region between the barrier element and the at least one side of the substrate to form a reservoir of thermal paste.

10. The method of claim 9, wherein the barrier element comprises one of a polymer, ceramic, plastic and metal material.

11. The method of claim 9, placing the barrier element comprises placing a plurality of capacitors along the at least one side of the integrated circuit chip.

12. The method of claim 9, wherein the reservoir is configured to receive thermal paste from the interface between the top surface of the integrated circuit chip and the bottom surface of the cap during expansion of at least one of the integrated circuit chip and the cap.

13. The method of claim 9, wherein the reservoir is configured to provide thermal paste to the interface between the top surface of the integrated circuit chip and the bottom surface of the cap during contraction of at least one of the integrated circuit chip and the cap.

14. The method of claim 9, wherein the thermal paste comprises any one or more of:
silicone oil;
mineral oil;
epoxy oil;
aluminum oxide;
zinc oxide; and
boron nitride.

15. An integrated circuit package, comprising:
a plurality of integrated circuit chips coupled with a substrate;
a cap configured as a heat dissipation element, wherein a thermal paste forms an interface between top surfaces of the integrated circuit chips and a bottom surface of the cap; and
at least one barrier element formed proximate to at least one side of at least one of the integrated circuit chips, wherein a region between the barrier element and the at least one side of the integrated circuit chip defines a reservoir for excess thermal paste pumped from between the top surface of the integrated circuit chip and the bottom surface of the cap

16. The system of claim 15, wherein the reservoir is configured to receive thermal paste from the interface between the top surface of the at least one integrated circuit chip and the bottom surface of the cap during expansion of at least one of the integrated circuit chip and the cap.

17. The system of claim 15, wherein the reservoir is configured to provide thermal paste to the interface between the top surface of the at least one integrated circuit chip and the bottom surface of the cap during contraction of at least one of the integrated circuit chip and the cap.

18. The system of claim 15, wherein the barrier element comprises one of a polymer, ceramic, plastic and metal material.

19. The system of claim 15, wherein the barrier element comprises a plurality of capacitors.

20. The system of claim 15, wherein the barrier element is attached to a surface of the substrate.
